(19) United States
(12) Patent Application Publication
(10) Pub. No.: US 2025/0040207 A1
(43) Pub. Date: Jan. 30, 2025

(54) SEMICONDUCTOR DEVICE

(71) Applicant: ROHM CO., LTD., Kyoto (JP)

(72) Inventor: Yusuke SHIMIZU, Kyoto-shi (JP)

(73) Assignee: ROHM CO., LTD., Kyoto (JP)

(21) Appl. No.: 18/918,729

(22) Filed: Oct. 17, 2024

Related U.S. Application Data
(63) Continuation of application No. PCT/JP2023/014503, filed on Apr. 10, 2023.

(30) Foreign Application Priority Data
Apr. 21, 2022 (JP) 2022-070180

(51) Int. Cl. H01L 29/08; H01L 29/10; H01L 29/49; H01L 29/872

(52) U.S. Cl. CPC H01L 29/0891; H01L 29/1095; H01L 29/4975; H01L 29/872

(57) ABSTRACT

A semiconductor device includes a semiconductor layer that is of a first conductivity type, a body region of a second conductivity type, a source region to be separated inwardly from an outer edge of the body region, a drain region formed on a surface of the semiconductor layer so as to be separated from the body region in a first direction orthogonal to a thickness direction of the semiconductor layer, a gate insulating layer formed on a portion of the surface of the semiconductor layer between the source region and the drain region in the first direction, a gate electrode that is formed on the gate insulating layer, an exposed region that is formed in the body region at a different position from the source region and in which the semiconductor layer is exposed, and a metal layer that forms a Schottky junction with the exposed region.

### BACKGROUND

The present disclosure relates to a semiconductor device.

A typical semiconductor device including a transistor, such as a metal-oxide-semiconductor field-effect-transistor (MOSFET), has a configuration in which a Schottky barrier diode is connected in antiparallel to the MOSFET so as to obtain stable high-speed operation of the transistor (refer to, for example, Japanese Laid-Open Patent Publication No. 2017-212286).

### BRIEF DESCRIPTION OF DRAWINGS

FIG. 1 is a schematic plan view of a semiconductor device in accordance with an embodiment.

FIG. 2 is a schematic cross-sectional view taken along line F2-F2 shown in FIG. 1.

FIG. 3 is an enlarged view of part F3 shown in FIG. 2.

FIG. 4 is a schematic cross-sectional view taken along line F4-F4 shown in FIG. 1.

FIG. 5 is an enlarged view of part F5 shown in FIG. 1.

FIG. 6 is a schematic circuit diagram of the semiconductor device shown in FIG. 1.

FIG. 7 is a schematic plan view of a semiconductor device in a modified example.

### DETAILED DESCRIPTION

An embodiment of a semiconductor device in accordance with the present disclosure will now be described with reference to the accompanying drawings. Elements in the drawings are illustrated for simplicity and clarity and have not necessarily been drawn to scale. To facilitate understanding, hatching lines may not be shown in the cross-sectional drawings. The accompanying drawings merely illustrate exemplary embodiments of the present disclosure and are not intended to limit the present disclosure.

This detailed description provides exemplary embodiments of methods, apparatuses, and/or systems in accordance with the present disclosure. The detailed description is illustrative and is not intended to limit embodiments of the present disclosure or the application and use of the embodiments.

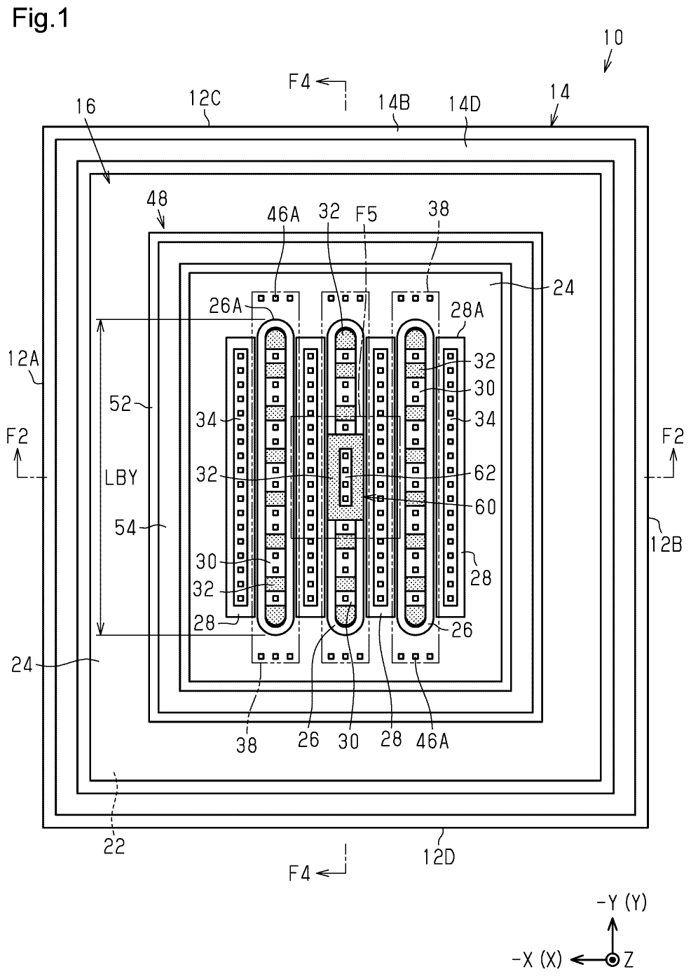

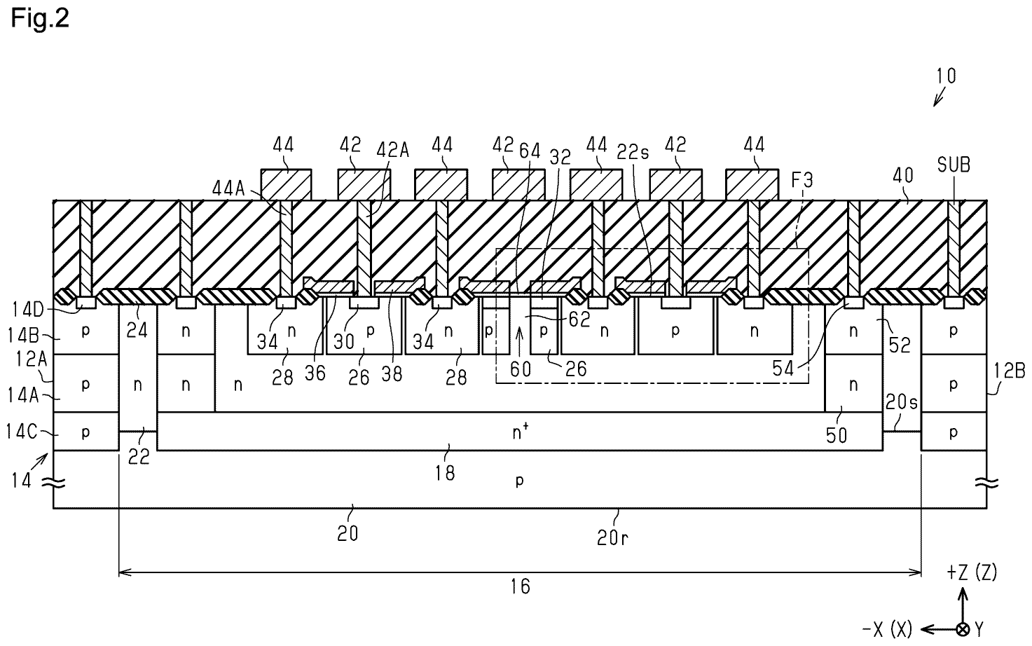

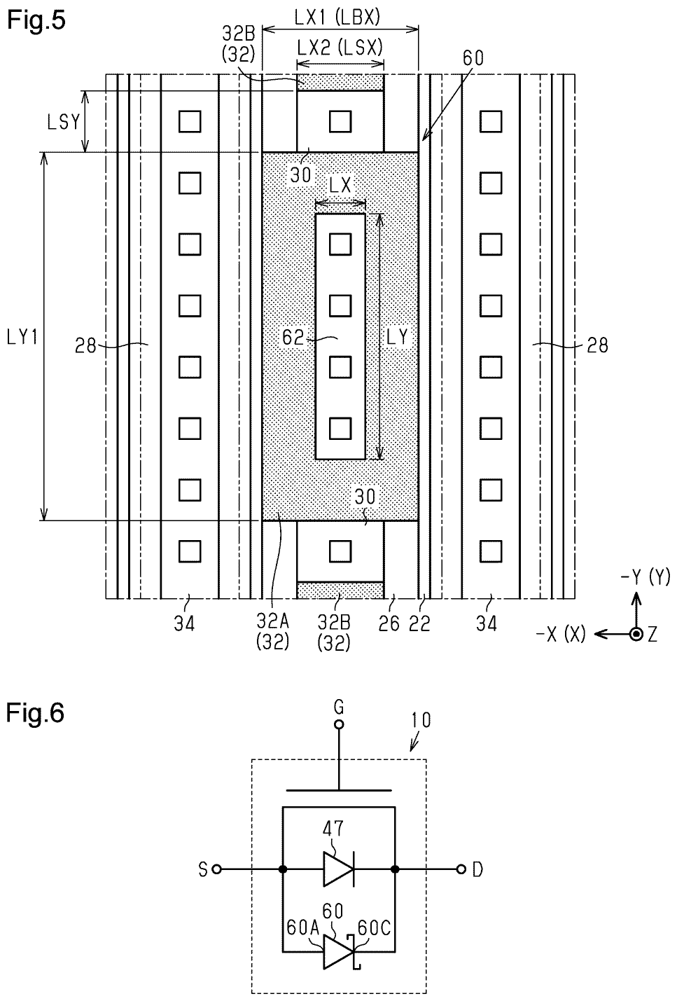

FIG. 1 schematically shows a planar structure of a semiconductor device 10. In FIG. 1, the configuration of the semiconductor device 10 is simplified to facilitate understanding. Further, in FIG. 1, an interlayer insulation layer 40, a source interconnection 42, a drain interconnection 44, and a metal layer 64, which will be described later, are not shown. FIGS. 2 to 4 schematically show cross-sectional structures of the semiconductor device 10. FIG. 5 shows an enlarged part of the structure of the semiconductor device 10 shown in FIG. 1. FIG. 6 shows a schematic circuit configuration of the semiconductor device 10.

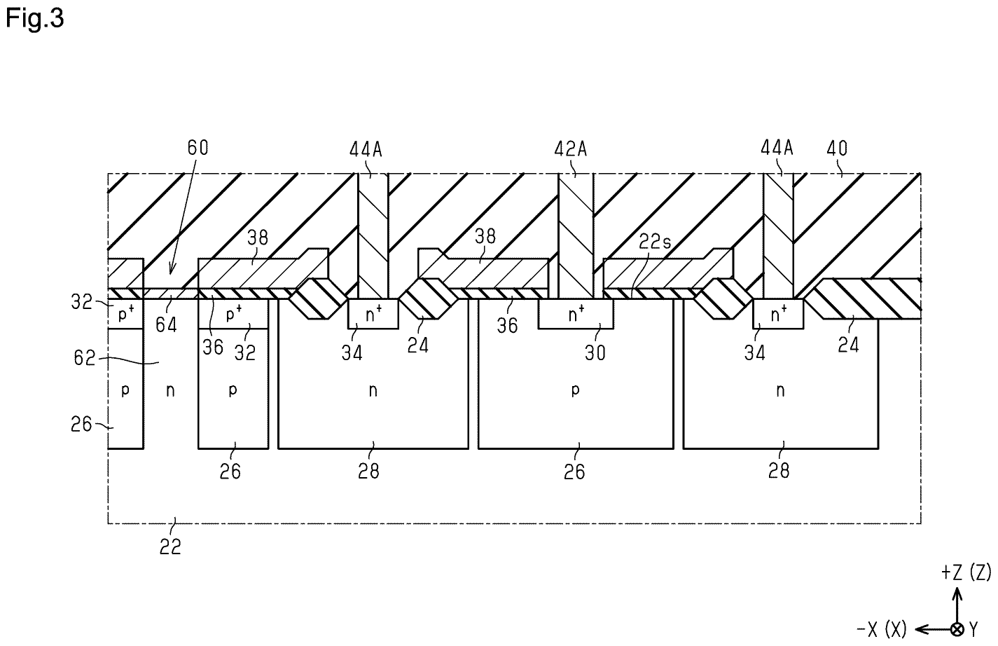

In this specification, the X-axis, Y-axis, and Z-axis are orthogonal to one another as shown in FIGS. 2 and 3. The term “plan view” as used in this specification refers to a view of the semiconductor device 10 taken in the Z-axis direction. Further, in FIGS. 2 and 3, which show the semiconductor device 10, the +Z direction corresponds to the upward direction, the −Z direction corresponds to the downward direction, the +X direction corresponds to the rightward direction, and the −X direction corresponds to the leftward direction. Unless otherwise indicated, the term “plan view” will refer to a view taken from above along the Z-axis of the semiconductor device 10. In the present embodiment, the X-axis direction corresponds to “first direction”, and the Y-axis direction corresponds to “second direction”.

As shown in FIG. 1, the semiconductor device 10 is rectangular in plan view. In the example shown in FIG. 1, the semiconductor device 10 has the form of a rectangle in which the short sides extend in the X-axis direction and the long sides extend in the Y-axis direction. The planar shape of the semiconductor device 10 may be changed in any manner.

The semiconductor device 10 includes device side surfaces 12A to 12D. The device side surface 12A and the device side surface 12B face each other in the X-axis direction. The device side surface 12C and the device side surface 12D face each other in the Y-axis direction. The device side surfaces 12A and 12B extend in the Y-axis direction in plan view. The device side surfaces 12C and 12D extend in the X-axis direction in plan view.

The semiconductor device 10 includes a cell region 16 surrounded by an element separator 14. In other words, the cell region 16 is defined by the element separator 14. A plurality of transistors are formed in the cell region 16. In the example shown in FIG. 1, the element separator 14 has the form of a rectangular frame with the short sides extending in the X-axis direction and the long sides extending in the Y-axis direction in plan view. Accordingly, the cell region 16 has the form of a rectangle in which the short sides extend in the X-direction and the long sides extend in the Y-direction in plan view. Further, in the example shown in FIG. 1, the element separator 14 includes the device side surfaces 12A to 12D. The planar shape of the cell region 16 may be changed in any manner.

As shown in FIG. 2, the semiconductor device 10 includes a p-type semiconductor substrate 20 and an n-type semiconductor layer 22 formed on the semiconductor substrate 20.

The semiconductor substrate 20 is formed from, for example, a material containing silicon (Si). In an example, the semiconductor substrate 20 is a Si substrate. The semiconductor substrate 20 may be a silicon carbide (SiC) substrate. The semiconductor substrate 20 has a thickness, for example, in a range of 100 μm to 500 μm, inclusive. The semiconductor substrate 20 has a p-type impurity concentration, for example, in a range of 1×10¹³ cm⁻³ to 1×10¹⁵ cm⁻³, inclusive. The semiconductor substrate 20 includes a substrate front surface 20s and a substrate back surface 20r. The substrate back surface 20r defines a device back surface of the semiconductor device 10.

The semiconductor layer 22 is formed on the substrate front surface 20s. In the present embodiment, the semiconductor layer 22 is in contact with the substrate front surface 20s. The semiconductor layer 22 is formed by an n-type epitaxial layer that has a thickness in the Z-direction. In other words, the Z-axis direction is the thickness-wise direction of the semiconductor layer 22. The semiconductor layer 22 is thinner than the semiconductor substrate 20 and has a thickness that is, for example, in a range of 3 μm to 20 μm, inclusive. The semiconductor layer 22 has an n-type impurity concentration, for example, in a range of 1×10¹⁴ cm⁻³ to 1×10¹⁶ cm⁻³, inclusive.

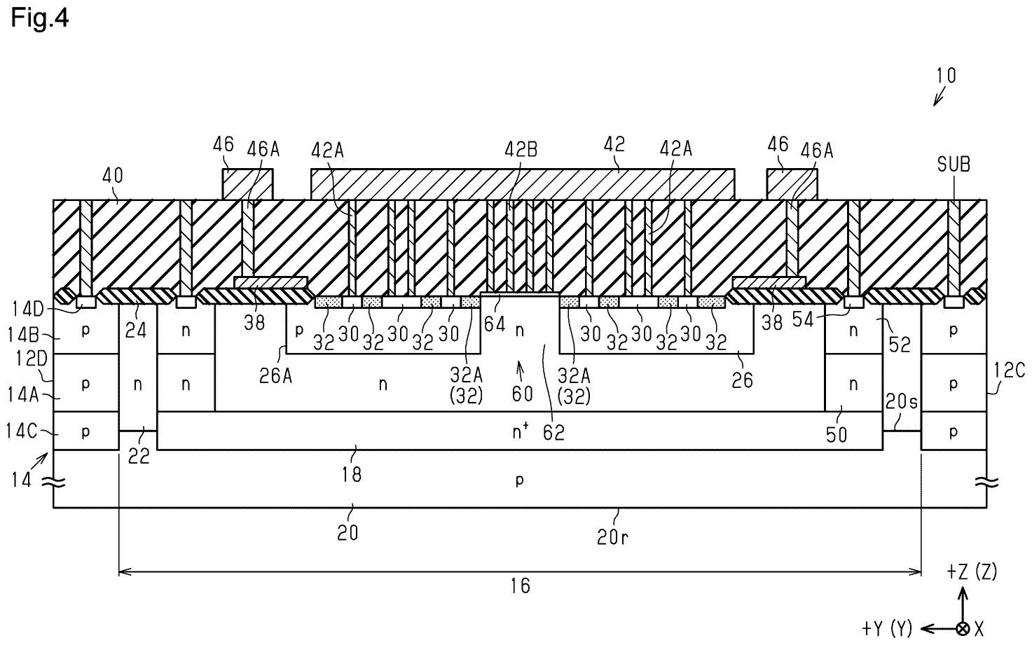

As shown in FIGS. 2 and 4, the element separator 14 is arranged at a periphery of the semiconductor layer 22. The element separator 14 includes a first isolation region 14A and a second isolation region 14B as p-type well regions, and a p-type embedded layer 14C.

The embedded layer 14C extends over a boundary of the semiconductor substrate 20 and the semiconductor layer 22. The embedded layer 14C has a thickness, for example, in a range of 2 μm to 3 μm, inclusive. The embedded layer 14C has a p-type impurity concentration that is higher than the n-type impurity concentration of the semiconductor layer 22.

The first isolation region 14A is formed on the embedded layer 14C. The second isolation region 14B is formed on the first isolation region 14A. The second isolation region 14B is exposed in a surface 22s of the semiconductor layer 22. In this manner, the element separator 14 extends through the semiconductor layer 22 in the Z-axis direction. The second isolation region 14B has a p-type impurity concentration that is higher than a p-type impurity concentration of the first isolation region 14A.

A p-type element separator contact region 14D is formed in a surface portion of the second isolation region 14B. The element separator contact region 14D has a p-type impurity concentration that is higher than the p-type impurity concentration of the second isolation region 14B.

As shown in FIGS. 2 and 4, the semiconductor device 10 includes an n⁺-type embedded layer 18 formed in the cell region 16, which is defined by the element separator 14. The embedded layer 18 has the form of a rectangle that is slightly smaller than the element separator 14 in plan view. As shown in FIGS. 2 and 4, the embedded layer 18 extends over the boundary of the semiconductor substrate 20 and the semiconductor layer 22. The embedded layer 18 has a thickness, for example, in a range of 2 μm to 3 μm, inclusive. The embedded layer 18 has a n-type impurity concentration that is higher than the n-type impurity concentration of the semiconductor layer 22.

In the present embodiment, an n-type corresponds to a first conductive type, and a p-type corresponds to a second conductive type. An n-type impurity may be, for example, phosphorus (P), arsenic (As), or the like. A p-type impurity may be, for example, boron (B), aluminum (Al), or the like.

The semiconductor device 10 includes a field insulation layer 24 formed on the surface 22s of the semiconductor layer 22. In the same manner as the element separator 14, the field insulation layer 24 has the form of a rectangular frame that surrounds the cell region 16 in plan view. Further, the field insulation layer 24 is also selectively formed in the cell region 16. The field insulation layer 24 is, for example, a local oxidation of silicon (LOCOS) film formed by selectively oxidizing the surface 22s of the semiconductor layer 22. The field insulation layer 24 is formed from, for example, silicon oxide (SiO₂). The field insulation layer 24 may be formed from a different insulative material such as silicon oxynitride (SiON) or the like.

### Configuration of Transistor

The configuration of the transistors in the cell region 16 will now be described.

The transistors in the cell region 16 include at least one of a metal oxide semiconductor field effect transistor (MOSFET), a bipolar junction transistor (BJT), an insulated gate bipolar transistor (IGBT), and a junction field effect transistor (JFET). In an example, the transistors include a MOSFET. In the present embodiment, the transistors include a laterally diffused (LD) MOSFET.

As shown in FIG. 2, the semiconductor device 10 includes a p-type first body region 26, an n-type second body region 28, an n⁺-type source region 30, a p⁺-type body contact region 32 (refer to FIG. 4), and an n⁺-type drain region 34. The first body region 26 and the second body region 28 are formed in the surface 22s of the semiconductor layer 22 in the cell region 16. The source region 30 and the body contact region 32 are formed in a surface of the first body region 26. The drain region 34 is formed in a surface of the second body region 28.

As shown in FIG. 1, a plurality of first body regions 26 and a plurality of second body regions 28 are formed. The body regions 26 and 28 extend in the Y-axis direction in plan view. The first body regions 26 and the second body regions 28 are alternately arranged in the X-axis direction. The first body regions 26 and the second body regions 28 are spaced apart from one another in the X-axis direction.

As shown in FIG. 2, the first body region 26 and the second body region 28 each have a thickness that is, for example, in a range of 0.5 μm to 4 μm, inclusive. The thickness of the first body region 26 may be defined by a distance between the surface 22s of the semiconductor layer 22 and a bottom surface of the first body region 26 in the Z-axis direction. The thickness of the second body region 28 may be defined by a distance between the surface 22s of the semiconductor layer 22 and a bottom surface of the second body region 28 in the Z-axis direction.

The bottom surfaces of the first body region 26 and the second body region 28 are located closer to the semiconductor substrate 20 than a bottom surface of the field insulation layer 24 is to the semiconductor substrate 20. The bottom surfaces of the first body region 26 and the second body region 28 are located closer to the surface 22s of the semiconductor layer 22 than the embedded layer 18 is to the semiconductor layer 22. A p-type impurity concentration of the first body region 26 and an n-type impurity concentration of the second body region 28 are both, for example, in a range of 1×10¹⁷ cm⁻³ to 1×10¹⁸ cm⁻³, inclusive.

As shown in FIGS. 1 and 4, the source region 30 and the body contact region 32 are formed in an inner part of the first body region 26 in plan view. The source region 30 and the body contact region 32 are separated from an edge 26A of the first body region 26 at positions located inward from the edge 26A of the first body region 26. The source region 30 and the body contact region 32 each have an edge extending parallel to the edge 26A of the first body region 26. A plurality of source regions 30 and a plurality of body contact regions 32 are formed. The source regions 30 and the body contact regions 32 are alternately arranged in the Y-axis direction. Adjacent ones of the source regions 30 and the body contact region 32 in the Y-axis direction are in contact with each other. The body contact regions 32 are also located at two opposite ends of the first body region 26 in the Y-axis direction. The arrangement of the source regions 30 and the body contact regions 32 is not limited to that shown in FIGS. 1 and 4, and may be changed in any manner.

The source region 30 has an n-type impurity concentration that is higher than the p-type impurity concentration of the first body region 26. The n-impurity concentration of the source region 30 is, for example, in a range of 1×10¹⁹ cm⁻³ to 5×10²¹ cm⁻³, inclusive. As shown in FIG. 2, the source region 30 is thinner than the first body region 26 and has a thickness that is, for example, in a range of 0.2 μm to 1 μm, inclusive.

The body contact region 32 has a p-type impurity concentration that is higher than the p-type impurity concentration of the first body region 26. The p-type impurity concentration of the body contact region 32 is, for example, in a range of 1×10¹⁹ cm⁻³ to 1×10²¹ cm⁻³, inclusive. The body contact region 32 is thinner than the first body region 26 and has a thickness that is, for example, in a range of 0.2 μm to 1 μm, inclusive.

As shown in FIG. 1, the drain region 34 is formed in an inner part of the second body region 28 in plan view. The drain region 34 is separated from an edge 28A of the second body region 28 at a position located inward from the edge 28A of the second body region 28. The drain region 34 extends in the Y-axis direction in plan view. The drain region 34 has an n-type impurity concentration that is higher than the n-type impurity concentration of the second body region 28. The n-type impurity concentration of the drain region 34 is, for example, in a range of 1×10¹⁹ cm⁻³ to 1×10²¹ cm⁻³, inclusive. As shown in FIG. 2, the drain region 34 is thinner than the second body region 28 and has a thickness that is, for example, in a range of 0.2 μm to 2 μm, inclusive.

As shown in FIG. 3, the semiconductor device 10 includes a gate insulation layer 36, a gate electrode 38, an interlayer insulation layer 40, a source interconnection 42, and a drain interconnection 44. The gate insulation layer 36 is formed on the surface 22s of the semiconductor layer 22. The gate electrode 38 is formed on the gate insulation layer 36. The interlayer insulation layer 40 covers the gate electrode 38. The source interconnection 42 and the drain interconnection 44 are formed on the interlayer insulation layer 40 (refer to FIG. 2).

The gate insulation layer 36 is formed on the surface 22s of the semiconductor layer 22 to cover an outer part of the first body region 26. The outer part of the first body region 26 corresponds to part of the first body region 26 that surrounds the source regions 30 and the body contact regions 32 in plan view. The gate insulation layer 36 is integrated with the field insulation layer 24. The gate insulation layer 36 is formed from, for example, SiO₂. The gate insulation layer 36 may be formed from a different insulation material such as SiON or the like. The gate insulation layer 36 is formed from, for example, the same material as the field insulation layer 24. The gate insulation layer 36 is thinner than the field insulation layer 24 and has a thickness that is, for example, in a range of 2 nm to 55 nm, inclusive.

The gate electrode 38 continuously extends over the gate insulation layer 36 onto the field insulation layer 24. That is, the gate electrode 38 covers part of the field insulation layer 24. The portion of the gate electrode 38 that covers the field insulation layer 24 forms a field plate.

As shown in FIG. 1, the gate electrode 38 has the form of a rectangular strip extending in the Y-axis direction. Two opposite ends of the gate electrode 38 in the Y-axis direction are located outward from the first body region 26. The gate electrode 38 includes a gate opening (not shown in FIG. 1) that exposes both the source region 30 and the body contact region 32. The gate electrode 38 is formed from, for example, a conductive polysilicon. The gate electrode 38 is formed from, for example, a polysilicon including an n-type impurity. The gate electrode 38 has an n-type impurity concentration, for example, in a range of 1×10¹⁹ cm⁻³ to 1×10²¹ cm⁻³, inclusive. The gate electrode 38 may be formed from, for example, a material containing at least one of cobalt (Co), hafnium (Hf), zirconium (Zr), Al, titanium (Ti), tantalum (Ta), and molybdenum (Mo).

As shown in FIG. 2, the interlayer insulation layer 40 covers the surface 22s of the semiconductor layer 22 along with the gate insulation layer 36, the gate electrode 38, and the field insulation layer 24. The interlayer insulation layer 40 at least covers the entire cell region 16. In the example shown in FIG. 2, the interlayer insulation layer 40 also covers the element separator 14. The interlayer insulation layer 40 is thicker than the field insulation layer 24 and has a thickness that is, for example, in a range of 0.3 μm to 2 μm, inclusive. The interlayer insulation layer 40 is formed from, for example, SiO₂. The interlayer insulation layer 40 may be formed from a different insulative material such as silicon nitride (SiN) or the like. The interlayer insulation layer 40 may have a stack structure including SiO₂ and SiN.

The source interconnection 42 formed on the interlayer insulation layer 40 is electrically connected to the source region 30. More specifically, the source interconnection 42 includes a source contact 42A extending through the interlayer insulation layer 40 in the Z-axis direction. The source contact 42A is arranged at a position to overlap the source region 30 in plan view, and is in contact with the source region 30. Thus, the source interconnection 42 is electrically connected to the source region 30. The source interconnection 42 is formed from, for example, a conductive material including at least one of Al, Cu, and Ti. In an example, the source interconnection 42 is formed from Al.

The drain interconnection 44 formed on the interlayer insulation layer 40 is electrically connected to the drain region 34. More specifically, the drain interconnection 44 includes a drain contact 44A extending through the interlayer insulation layer 40 in the Z-axis direction. The drain contact 44A is arranged at a position to overlap the drain region 34 in plan view, and is in contact with the drain region 34. Thus, the drain interconnection 44 is electrically connected to the drain region 34. The drain interconnection 44 is formed from, for example, a conductive material including at least one of Al, Cu, and Ti. In an example, the drain interconnection 44 is formed from Al.

As shown in FIG. 4, a gate interconnection 46 is formed on the interlayer insulation layer 40. In the same manner as the source interconnection 42 and the drain interconnection 44 (refer to FIG. 2), the gate interconnection 46 is electrically connected to the gate electrode 38 by a gate contact 46A. As shown in FIG. 1, the gate contacts 46A are arranged at positions to overlap the two opposite ends of the gate electrode 38 in the Y-axis direction in plan view. The gate interconnection 46 is formed from, for example, a conductive material including at least one of Al, Cu, and Ti. In an example, the gate interconnection 46 is formed from Al.

The source contact 42A, the drain contact 44A, and the gate contact 46A may each be formed from a conductive material that differs from the materials of the source interconnection 42, the drain interconnection 44, and the gate interconnection 46. In an example, the source contact 42A, the drain contact 44A, and the gate contact 46A are each formed from a material containing tungsten (W).

In the semiconductor device 10, a body diode 47 is formed by the p-type first body region 26 and the n-type semiconductor layer 22 (refer to FIG. 6). The anode of the body diode 47 is electrically connected to the source region 30, and the cathode of the body diode 47 is electrically connected to the drain region 34. That is, the body diode 47 is connected in antiparallel to the transistor in the cell region 16.

As shown in FIG. 1, the semiconductor device 10 includes an n-type guard ring 48 that surrounds the first body regions 26 and the second body regions 28. In other words, the guard ring 48 surrounds the source regions 30, the body contact regions 32, and the drain regions 34 in plan view. Further, the guard ring 48 surrounds the gate electrode 38 in plan view. The guard ring 48 is arranged at a position to overlap a peripheral part of the embedded layer 18 in plan view. Accordingly, in plan view, the guard ring 48 has the form of a rectangular frame with the short sides extending in the X-direction and the long sides extending in the Y-direction.

As shown in FIGS. 1 and 2, the guard ring 48 includes a first ring region 50 and a second ring region 52. The first ring region 50 is formed on the embedded layer 18. The second ring region 52 formed on the first ring region 50. The second ring region 52 is exposed in the surface 22s of the semiconductor layer 22. In this manner, the transistors in the cell region 16 are surrounded by the guard ring 48 and the embedded layer 18 in the X-axis direction, the Y-axis direction, and the Z-axis direction. The second ring region 52 has an n-type impurity concentration that is higher than an n-type impurity concentration of the first ring region 50. Further, the guard ring 48 and the embedded layer 18 are both electrically floating.

An n-type ring contact region 54 is formed in a surface portion of the second ring region 52. The ring contact region 54 has an n-type impurity concentration that is higher than the n-type impurity concentration of the second ring region 52.

### Configuration of Schottky Barrier Diode

As shown in FIG. 6, the semiconductor device 10 includes a Schottky barrier diode (hereafter, “SBD 60”). In other words, the SBD 60 is incorporated in the semiconductor device 10. The SBD 60 includes an anode electrode 60A and a cathode electrode 60C. The anode electrode 60A is electrically connected to the source of the transistor of the semiconductor device 10. The cathode electrode 60C is electrically connected to the drain of the transistor. Thus, the SBD 60 is connected in parallel to the body diode 47.

The configuration of the SBD 60 will now be described with reference to FIGS. 1 to 5.

As shown in FIG. 1, the SBD 60 is formed in a central part of the cell region 16 in plan view. More specifically, the SBD 60 is formed in a central part of the first body region 26 in the Y-axis direction, the first body region 26 being located in the middle of three first body regions 26 in the X-axis direction. In other words, the SBD 60 is formed in the first body region 26 in plan view.

As shown in FIGS. 2 to 4, the SBD 60 includes an exposed region 62 and a metal layer 64 that forms a Schottky junction with the exposed region 62.

The exposed region 62 exposes the semiconductor layer 22 from the first body region 26. In the exposed region 62, the semiconductor layer 22 extends through the first body region 26 in the Z-axis direction.

As shown in FIG. 1, the exposed region 62 is arranged at a central part of the first body region 26 in the X-axis direction and the Y-axis direction. Accordingly, as shown in FIG. 5, in plan view, a length LX of the exposed region 62 in the X-axis direction is less than a length LBX of the first body region 26 in the X-axis direction. In plan view, a length LY of the exposed region 62 in the Y-axis direction is less than a length LBY of the first body region 26 in the Y-axis direction (refer to FIG. 1).

In plan view, the exposed region 62 has the form of a rectangle in which the short sides extend in the X-direction and long sides extend in the Y-direction. The length LY of the exposed region 62 in the Y-axis direction is less than the length LBY of the first body region 26 in the Y-axis direction. The length LY of the exposed region 62 in the Y-axis direction is less than one-half of the length LBY of the first body region 26 in the Y-axis direction. The length LX of the exposed region 62 in the Y-axis direction is less than one-third of the length LBY of the first body region 26 in the Y-axis direction. The length LY of the exposed region 62 in the Y-axis direction is greater than one-fourth of the length LBY of the first body region 26 in the Y-axis direction.

As shown in FIG. 5, the body contact region 32 includes a first body contact region 32A and a second body contact region 32B. The first body contact region 32A surrounds the exposed region 62 in plan view. The second body contact region 32B does not surround the exposed region 62. The first body contact region 32A forms part of the SBD 60.

The first body contact region 32A is in contact with the exposed region 62. In this manner, the exposed region 62 is surrounded by the p-type first body region 26 and the p-type first body contact region 32A. In the example shown in FIG. 5, the first body contact region 32A has the form of a rectangular frame in plan view. In other words, the exposed region 62 extends through the first body contact region 32A in the Z-axis direction. Accordingly, the exposed region 62 extends through both the first body contact region 32A and the first body region 26 in the Z-axis direction.

The second body contact region 32B is formed in the first body region 26 at a position separated from the exposed region 62 in plan view. In the example shown in FIG. 5, a plurality of second body contact regions 32B are formed in each of the first body regions 26. The second body contact regions 32B are spaced apart from one another in the Y-axis direction. The second body contact regions 32B are separated from the first body contact region 32A.

In the example shown in FIG. 5, a length LX1 of the first body contact region 32A in the X-axis direction is greater than a length LX2 of the second body contact region 32B in the X-axis direction. Further, the length LX1 is greater than a length LSX of the source region 30 in the X-axis direction. The length LX2 is equal to the length LSX.

In the example shown in FIG. 5, a length LY1 of the first body contact region 32A in the Y-axis direction is greater than a length of the second body contact region 32B in the Y-axis direction. Further, the length LY1 is greater than a length LSY of the source region 30 in the Y-axis direction.

In the example shown in FIG. 5, the length LX of the exposed region 62 in the X-axis direction is less than the length LX2 of the second body contact region 32B in the X-axis direction. The length LY of the exposed region 62 in the Y-axis direction is greater than the length of the second body contact region 32B in the Y-axis direction. The length LY is greater than the length LSY of the source region 30 in the Y-axis direction.

As shown in FIG. 3, the metal layer 64 is formed on the surface 22s of the semiconductor layer 22. More specifically, the metal layer 64 is arranged at a position to overlap the source region 30, the body contact region 32, and the exposed region 62 in plan view. In an example, the metal layer 64 has the form of a strip extending in the Y-axis direction in plan view. The metal layer 64 is in contact with each of the source region 30, the body contact region 32, and the exposed region 62. Thus, the metal layer 64 is electrically connected to the source region 30, the body contact region 32, and the exposed region 62. The metal layer 64 is formed from, for example, silicide. The metal layer 64 does not have to be formed from silicide, and may be formed from any type of conductive material.

Since the exposed region 62 is formed by the semiconductor layer 22, the n-type impurity concentration of the exposed region 62 is relatively low. A Schottky junction is formed between the metal layer 64 and the exposed region 62 at where the exposed region 62 is in contact with the metal layer 64. In this manner, the SBD 60 is formed by the Schottky junction between the semiconductor layer 22, which serves as the exposed region 62, and the metal layer 64, which is formed from silicide. In this case, the metal layer 64 forms the anode of the SBD 60, and the semiconductor layer 22 forms the cathode of the SBD 60.

The metal layer 64 is electrically connected to the source interconnection 42. More specifically, the source interconnection 42 includes a diode contact 42B extending through the interlayer insulation layer 40 in the Z-axis direction. The diode contact 42B is arranged at a position to overlap the metal layer 64 (exposed region 62) in plan view, and is in contact with the metal layer 64. Thus, the source interconnection 42 is electrically connected to the metal layer 64.

In the example shown in FIG. 4, multiple (four) diode contacts 42B are arranged. The diode contacts 42B are aligned in the X-axis direction and are spaced apart from one another in the Y-axis direction.

The diode contacts 42B may be formed from a conductive material that differs from the material of the source interconnection 42. In an example, the diode contact 42B is formed from a material containing tungsten (W).

### Operation

The operation of the semiconductor device 10 in the present embodiment will now be described.

When a transistor and a Schottky barrier diode (SBD) are arranged as separate chips, a semiconductor device will be increased in size. Accordingly, the transistor and the SBD may be arranged on the same chip. In this case, the chip includes a semiconductor substrate and a semiconductor layer formed on the semiconductor substrate. The transistor and the SBD are, for example, both formed on the semiconductor layer. More specifically, the semiconductor layer includes a first region in which the transistor is formed and a second region in which the SBD is formed. The first region and the second region are separated from each other by an element separator. In this manner, when the first and second regions are separated from each other, the element separator arranged between the two regions may enlarge the chip. That is, the semiconductor device will be increased in size. In addition, since the transistor is separated from the SBD, wiring may be arranged to electrically connect the anode and cathode of the SBD to the drain and source of the transistor. This may delay the operation of the SBD with respect to the transistor and, in turn, hinder the high-speed operation of the transistor.

In this respect, in the present embodiment, the SBD 60 is formed in a region where the transistor is formed. Specifically, the SBD 60 is formed in the first body region 26 in plan view. Thus, the semiconductor device 10 will not be enlarged even when the SBD 60 is arranged. Further, the SBD 60 includes the semiconductor layer 22, which serves as the exposed region 62, thereby eliminating the need for the wiring that connects the SBD 60 and the transistor of the semiconductor device 10. This contributes to the high-speed operation of the transistor.

### Advantages

The semiconductor device 10 of the present embodiment has the following advantages.
(1) The semiconductor device 10 includes the n-type semiconductor layer 22, the p-type first body region 26, the n-type source region 30, the n-type drain region 34, the gate insulation layer 36, the gate electrode 38, the exposed region 62, and the metal layer 64. The semiconductor layer 22 has the surface 22s. The first body region 26 is formed in the surface 22s of the semiconductor layer 22. The source region 30 is formed within the first body region 26 and is separated from the edge 26A of the first body region 26. The drain region 34 is formed in the surface 22s of the semiconductor layer 22 and is separated from the first body region 26 in the X-axis direction. The gate insulation layer 36 is formed on the surface 22s of the semiconductor layer 22 at a portion located between the source region 30 and the drain region 34 in the X-axis direction. The gate electrode 38 is formed on the gate insulation layer 36. The exposed region 62 is formed in the first body region 26 at a position differing from the source region 30 and exposes the semiconductor layer 22. The metal layer 64 forms a Schottky junction with the exposed region 62.
With this configuration, the exposed region 62 (semiconductor layer 22) and the metal layer 64 form the Schottky barrier diode (SBD 60). Since the exposed region 62 is formed in the first body region 26 in plan view, the SBD 60 is arranged in the first body region 26 in plan view. This limits enlargement of the semiconductor device 10 as compared to a semiconductor device including a semiconductor layer in which a transistor is formed in a first region and an SBD is formed in a second region.
(2) The exposed region 62 extends in the Y-axis direction in plan view.
With this configuration, the exposed region 62 extends in the same direction as the direction (long-side direction) in which the first body region 26 extends. Thus, the length of the exposed region 62 in the Y-axis direction can be easily adjusted. This contributes to the desired performance of the SBD 60.
(3) The semiconductor device 10 includes the p-type body contact region 32 formed in the surface 22s of the semiconductor layer 22. The source region 30 and the body contact region 32 are alternately arranged in the Y-axis direction. The exposed region 62 is surrounded by the body contact region 32 in plan view.
With this configuration, the n-type exposed region 62 is surrounded by the p-type body contact region 32 and the p-type first body region 26 in plan view. This avoids generation of a leakage current.
(4) The semiconductor device 10 further includes the interlayer insulation layer 40, the source interconnection 42, and the diode contact 42B. The interlayer insulation layer 40 covers the surface 22s of the semiconductor layer 22 along with the field insulation layer 24, the gate insulation layer 36, and the gate electrode 38. The source interconnection 42 is formed on the interlayer insulation layer 40 and is electrically connected to the source region 30. The diode contact 42B extends through the interlayer insulation layer 40 and electrically connects the source interconnection 42 and the metal layer 64.

This configuration electrically connects the metal layer 64, which forms the anode of the SBD 60, and the source interconnection 42, which is connected to the source of the transistor of the semiconductor device 10. In other words, in the semiconductor device 10, the anode of the SBD 60 is electrically connected to the source of the transistor. This shortens the electrical path between the anode of the SBD 60 and the source of transistor.

### MODIFIED EXAMPLES

The embodiment described above may be modified as follows. The above embodiment and the modified examples described below may be combined as long as there is no technical contradiction.

The exposed region 62 does not have to be located at the central part of the first body region 26 in the Y-axis direction. The arrangement of the exposed region 62 in the first body region 26 may be changed in any manner. In an example, the exposed region 62 may be arranged at an end of the first body region 26 in the Y-axis direction.

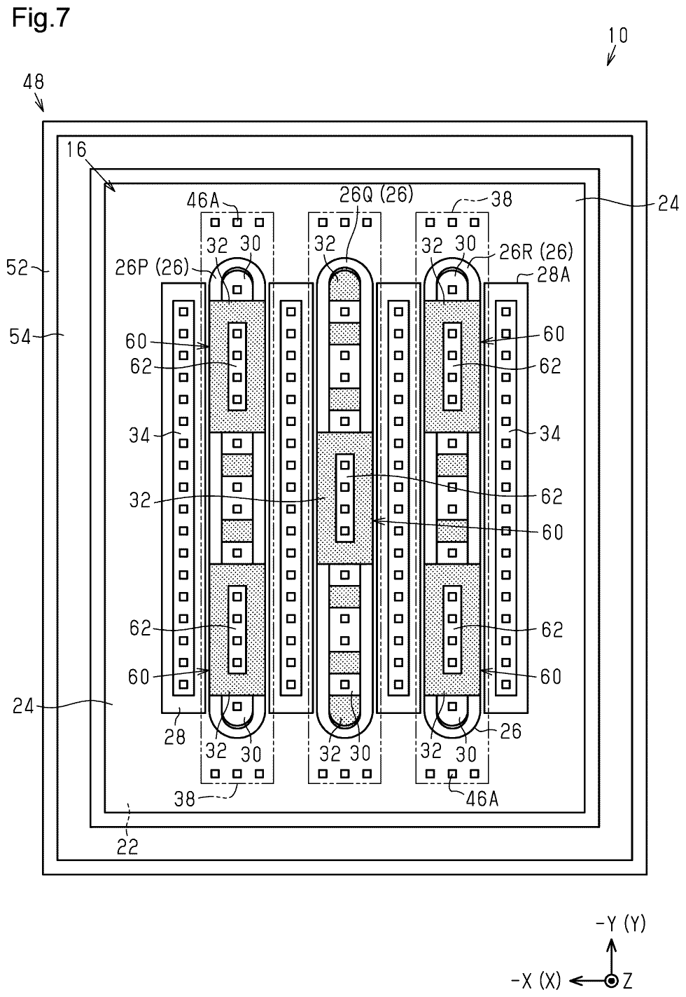

There may be multiple exposed regions 62. In this case, the exposed regions 62 are separated from one another. In an example, as shown in FIG. 7, the exposed regions 62 may be spaced apart from one another in the X-axis direction and the Y-axis direction in plan view. In FIG. 7, to facilitate understanding, three first body regions 26 will be respectively referred to as “first body region 26P”, “first body region 26Q”, and “first body region 26R”. The first body region 26Q is located between the first body region 26P and the first body region 26Q in the X-axis direction. The first body region 26P is located closer to the device side surface 12A than the first body region 26Q is to the device side surface 12A. The first body region 26R is located closer to the device side surface 12B than the first body region 26Q is to the device side surface 12B.

In the example shown in FIG. 7, the first body regions 26P and 26R each include two exposed regions 62. The two exposed regions 62 formed in the first body region 26P are located at two opposite ends of the first body region 26P in the Y-axis direction. The two exposed regions 62 formed in the first body region 26R are located at two opposite ends of the first body region 26R in the Y-axis direction. The single exposed region 62 formed in the first body region 26Q is located at a central part of the first body region 26Q in the Y-axis direction. In this manner, the semiconductor device 10 may include multiple SBDs 60.

The arrangement of the exposed regions 62 in the first body region 26 and the number of the exposed regions 62 may be changed in any manner. That is, the number of exposed regions 62 may be adjusted in accordance with the specifications of the transistor and the SBD 60 of the semiconductor device 10. This increases the degree of freedom for designing the semiconductor device 10, thereby improving the usability of the semiconductor device 10.

The exposed region 62 does not have to extend in the Y-axis direction in plan view. The exposed region 62 may extend, for example, in the X-axis direction in plan view. In an example, the exposed region 62 has the form of a rectangle in which the long sides extend in the X-direction and the short sides extend in the Y-direction.

The length LX of the exposed region 62 in the X-axis direction may be changed in any manner. In an example, the length LX may be greater than or equal to the length of the second body contact region 32B in the X-axis direction.

The length LY of the exposed region 62 in the Y-axis direction may be changed in any manner. In an example, the length LY may be less than or equal to the length of the second body contact region 32B in the Y-axis direction.

The length LX2 of the second body contact region 32B in the X-axis direction may be changed in any manner. In an example, the length LX2 may be greater than or equal to the length LX1 of the first body contact region 32A in the X-axis direction.

The length of the second body contact region 32B in the Y-axis direction may be changed in any manner. In an example, the length of the second body contact region 32B in the Y-axis direction may be greater than or equal to the length LY1 of the first body contact region 32A in the Y-axis direction.

The metal layer 64 does not have to be formed from silicide, and the material may be changed in any manner. The metal layer 64 may be formed from any material as long as the material allows for formation of a Schottky junction with the exposed region 62.

The second body region 28 can be omitted from the semiconductor device 10.

In this specification, “at least one of A and B” should be understood to mean “only A, only B, or both A and B”.

In the present disclosure, the term “on” includes the meaning of “above” in addition to the meaning of “on” unless otherwise clearly described in the context. Accordingly, the phrase “first layer formed on second layer” may mean that the first layer is formed directly contacting the second layer in one embodiment and that the first layer is located above the second layer without contacting the second layer in another embodiment. Thus, the term “on” will also allow for a structure in which another layer is formed between the first layer and the second layer.

The terms used in this disclosure to indicate directions such as “vertical”, “horizontal”, “upward”, “downward”, “top”, “bottom”, “forward”, “backward”, “side”, “left”, “right”, “front”, and “back” will be attributed to specific directions of the described and illustrated device. In the present disclosure, a variety of alternative directions may be available for any given direction. Thus, directional terms should not be construed narrowly.

### CLAUSES

Technical concepts that can be understood from the above embodiment and modified examples will now be described. Reference characters shown in parenthesis in the clauses described below denote corresponding elements of the embodiment described above to facilitate understanding without any intention to impose limitations on these elements. The reference characters are given as examples to aid understanding and not intended to limit elements to the elements denoted by the reference characters.

### Clause 1

A semiconductor device (10), including:
a semiconductor layer (22) of a first conductive type having a surface (22s);
a body region (26) of a second conductive type formed in the surface (22s) of the semiconductor layer (22);
a source region (30) of the first conductive type formed within the body region (26) and separated from an edge (26A) of the body region (26);
a drain region (34) of the first conductive type formed in the surface (22s) of the semiconductor layer (22) and separated from the body region (26) in a first direction (X-axis direction) orthogonal to a thickness-wise direction (Z-axis direction) of the semiconductor layer (22);
a gate insulation layer (36) formed on the surface (22s) of the semiconductor layer (22) at a portion located between the source region (30) and the drain region (34) in the first direction (X-axis direction);
a gate electrode (38) formed on the gate insulation layer (36);
an exposed region (62) formed in the body region (26) at a position differing from the source region (30) and exposing the semiconductor layer (22); and
a metal layer (64) forming a Schottky junction with the exposed region (62).

### Clause 2

The semiconductor device according to clause 1, in which the exposed region (60) extends in a second direction (Y-axis direction) orthogonal to the first direction (X-axis direction) in plan view.

### Clause 3

The semiconductor device according to clause 1 or 2, further including:
a body contact region (32) of the second conductive type formed in the surface (22s) of the semiconductor layer (22), in which
the source region (30) and the body contact region (32) are alternately arranged in a second direction (Y-axis direction) orthogonal to the first direction (X-axis direction) in plan view, and
the exposed region (62) is surrounded by the body contact region (32) in plan view.

### Clause 4

The semiconductor device according to clause 3, in which
the body contact region (32) includes
   a first body contact region (32A) surrounding the exposed region (62), and
   a second body contact region (32B) that does not surround the exposed region (62), and
a length (LX1) of the first body contact region (32A) in the first direction (X-axis direction) is greater than a length (LX2) of the second body contact region (32B) in the first direction (X-axis direction).

### Clause 5

The semiconductor device according to clause 4, in which a length (LY1) of the first body contact region (32A) in the second direction (Y-axis direction) is greater than a length of the second body contact region (32B) in the second direction (Y-axis direction).

### Clause 6

The semiconductor device according to clause 4 or 5, in which a length (LY) of the exposed region (62) in the second direction (Y-axis direction) is greater than a length of the length (LY) of the second body contact region (32B) in the second direction (Y-axis direction).

### Clause 7

The semiconductor device according to any one of clauses 4 to 6, in which a length (LX) of the exposed region (62) in the first direction (X-axis direction) is less than the length (LX2) of the second body contact region (32B) in the first direction (X-axis direction).

### Clause 8

The semiconductor device according to any one of clauses 1 to 7, in which
the exposed region (62) is exposed regions, and
the exposed regions (62) are separated from each other.

### Clause 9

The semiconductor device according to any one of clauses 1 to 8, in which the metal layer (64) is formed on the surface (22s) of the semiconductor layer (22) and is in contact with the exposed region (64).

### Clause 10

The semiconductor device according to clause 9, in which the metal layer (64) is formed from silicide.

### Clause 11

The semiconductor device according to any one of clauses 1 to 10, further including:
an interlayer insulation layer (40) covering the surface (22s) of the semiconductor layer (22) along with the gate insulation layer (36) and the gate electrode (38);
a source interconnection (42) formed on the interlayer insulation layer (40) and electrically connected to the source region (30); and
a diode contact (42B) extending through the interlayer insulation layer (40) and electrically connecting the source interconnection (42) and the metal layer (64).

### Clause 12

The semiconductor device according to any one of clauses 1 to 11, in which a length (LX) of the exposed region (62) in the first direction (X-axis direction) is less than a length (LSX) of the source region (30) in the first direction (X-axis direction).

### Clause 13

The semiconductor device according to any one of clauses 1 to 12, in which, when a direction orthogonal to the first direction (X-axis direction) in plan view is a second direction (Y-axis direction), a length (LY) of the exposed region (62) in the second direction (Y-axis direction) is greater than a length (LSY) of the source region (30) in the second direction (Y-axis direction).

### Clause 14

The semiconductor device according to any one of clauses 4 to 6, in which the length (LX1) of the first body contact region (32A) in the first direction (X-axis direction) is greater than a length (LSX) of the source region (30) in the first direction (X-axis direction).

### Clause 15

The semiconductor device according to any one of clauses 4 to 6, in which, when a direction orthogonal to the first direction (X-axis direction) in plan view is a second direction (Y-axis direction), a length (LY1) of the first body contact region (32A) in the second direction (Y-axis direction) is greater than a length (LSY) of the source region (30) in the second direction (Y-axis direction).

### Clause 16

The semiconductor device according to any one of clauses 4 to 6, in which the length (LX1) of the first body contact region (32A) in the first direction (X-axis direction) is equal to a length (LBX) of the body region (26) in the first direction (X-axis direction).

Exemplary descriptions are given above. In addition to the elements and methods (manufacturing processes) described to illustrate the technology of this disclosure, a person skilled in the art would recognize the potential for a wide variety of combinations and substitutions. All replacements, modifications, and variations within the scope of the claims are intended to be encompassed in the present disclosure.

### REFERENCE SIGNS LIST

10) semiconductor device
12A to 12D) device side surfaces
14) element separator
14A) first isolation region
14B) second isolation region
14C) embedded layer
14D) element separator contact region
16) cell region
18) embedded layer
20) semiconductor substrate
22) semiconductor layer
22s) surface
24) field insulation layer
26, 26P, 26Q, 26R) first body regions
26A) edge
28) second body region
30) source region
32) body contact region
32A) first body contact region
32B) second body contact region
34) drain region
36) gate insulation layer
38) gate electrode
40) interlayer insulation layer
42) source interconnection
42A) source contact
42B) diode contact
44) drain interconnection
44A) drain contact
46) gate interconnection
46A) gate contact
47) body diode
48) guard ring
50) first ring region
52) second ring region
54) ring contact region
60) Schottky barrier diode (SBD)
60A) anode electrode
60C) cathode electrode
62) exposed region
64) metal layer
LX1) length of first body contact region
LY1) length of first body contact region
LX2) length of second body contact region
LSX) length of source region
LSY) length of source region
LX) length of exposed region
LY) length of exposed region
LBX) length of first body region
LBY) length of first body region

1. A semiconductor device, comprising:
a semiconductor layer of a first conductive type having a surface;
a body region of a second conductive type formed in the surface of the semiconductor layer;
a source region of the first conductive type formed within the body region and separated from an edge of the body region;
a drain region of the first conductive type formed in the surface of the semiconductor layer and separated from the body region in a first direction orthogonal to a thickness-wise direction of the semiconductor layer;
a gate insulation layer formed on the surface of the semiconductor layer at a portion located between the source region and the drain region in the first direction;
a gate electrode formed on the gate insulation layer;
an exposed region formed in the body region at a position differing from the source region and exposing the semiconductor layer; and
a metal layer forming a Schottky junction with the exposed region.

2. The semiconductor device according to claim 1, wherein the exposed region extends in a second direction orthogonal to the first direction in plan view.

3. The semiconductor device according to claim 1, further comprising:
a body contact region of the second conductive type formed in the surface of the semiconductor layer, wherein
the source region and the body contact region are alternately arranged in a second direction orthogonal to the first direction in plan view, and
the exposed region is surrounded by the body contact region in plan view.

4. The semiconductor device according to claim 3, wherein
the body contact region includes
a first body contact region surrounding the exposed region, and
a second body contact region that does not surround the exposed region, and
a length of the first body contact region in the first direction is greater than a length of the second body contact region in the first direction.

5. The semiconductor device according to claim 4, wherein a length of the first body contact region in the second direction is greater than a length of the second body contact region in the second direction.

6. The semiconductor device according to claim 5, wherein a length of the exposed region in the second direction is greater than the length of the second body contact region in the second direction.

7. The semiconductor device according to claim 4, wherein a length of the exposed region in the first direction is less than the length of the second body contact region in the first direction.

8. The semiconductor device according to claim 1, wherein
the exposed region comprises exposed regions, and
the exposed regions are separated from each other.

9. The semiconductor device according to claim 1, wherein the metal layer is formed on the surface of the semiconductor layer and is in contact with the exposed region.

10. The semiconductor device according to claim 9, wherein the metal layer is formed from silicide.

11. The semiconductor device according to claim 1, further comprising:
an interlayer insulation layer covering the surface of the semiconductor layer along with the gate insulation layer and the gate electrode;
a source interconnection formed on the interlayer insulation layer and electrically connected to the source region; and
a diode contact extending through the interlayer insulation layer and electrically connecting the source interconnection and the metal layer.
